(19) United States
(12) Patent Application Publication
(10) Pub. No.: US 2026/0286517 A1
(43) Pub. Date: Sep. 24, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Yosuke WATANABE, Toyama-shi (JP); Masayuki ASAI, Toyama-shi (JP); Saaya KUROO, Toyama-shi (JP); Atsushi SANO, Toyama-shi (JP)

(73) Assignee: Kokusai Electric Corporation, Tokyo (JP)

(21) Appl. No.: 19/647,495

(22) Filed: Apr. 14, 2026

Related U.S. Application Data
(63) Continuation of application No. PCT/JP2024/034536, filed on Sep. 26, 2024.

(30) Foreign Application Priority Data
Mar. 26, 2024 (JP) 2024-049403

(51) Int. Cl. C23C 16/455; C23C 16/40; C23C 16/56; H10P 14/60; H10P 14/692

(52) U.S. Cl. CPC C23C 16/45527; C23C 16/405; C23C 16/56; H10P 14/6339; H10P 14/69392; H10P 14/69395

(57) ABSTRACT

A technique includes: (a) supplying a first precursor to a substrate, (b) supplying a first reactant to the substrate in a first amount, (c) supplying a second reactant to the substrate in a second amount, (d) performing (a) and (b) a predetermined number of times to form a first layer on the substrate, and (e) performing (a) and (c) a predetermined number of times to form a second layer on the substrate.

### CROSS-REFERENCE TO RELATED APPLICATION

This application is a Bypass Continuation Application of PCT International Application No. PCT/JP2024/034536, filed on Sep. 26, 2024, and designating the United States, the international application being based upon and claiming the benefit of priority from Japanese Patent Application No. 2024-049403, filed on Mar. 26, 2024, the disclosure of which is incorporated herein in its entirety by reference.

### TECHNICAL FIELD

The present disclosure relates to a method of processing a substrate, a method of manufacturing a semiconductor device, a recording medium, and a substrate processing apparatus.

### BACKGROUND

As a substrate processing process, a process of forming a film on a substrate may be performed (see, e.g., Patent Document 1).

### SUMMARY

Some embodiments of the present disclosure provide a technique capable of improving characteristics of a film.

According to one embodiment of the present disclosure, there is provided a technique that includes:
(a) supplying a first precursor to a substrate;
(b) supplying a first reactant to the substrate in a first amount;
(c) supplying a second reactant to the substrate in a second amount;
(d) performing (a) and (b) a predetermined number of times to form a first layer on the substrate; and
(e) performing (a) and (c) a predetermined number of times to form a second layer on the substrate.

### BRIEF DESCRIPTION OF DRAWINGS

The accompanying drawings, which are incorporated in and constitute a part of the specification, illustrate embodiments of the present disclosure.

FIG. 1 is a longitudinal sectional view schematically illustrating a substrate processing apparatus.

FIG. 2 is a schematic cross-sectional view taken along line A-A in FIG. 1.

FIG. 3 is a schematic configuration diagram of a controller of the substrate processing apparatus, in which a control system of the controller is shown in a block diagram.

FIG. 4 is a flowchart illustrating a series of processes including a substrate processing process.

FIG. 5 is a flowchart illustrating processes from a first process to a modification process.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are described in detail so as not to obscure aspects of the various embodiments.

### One Embodiment of the Present Disclosure

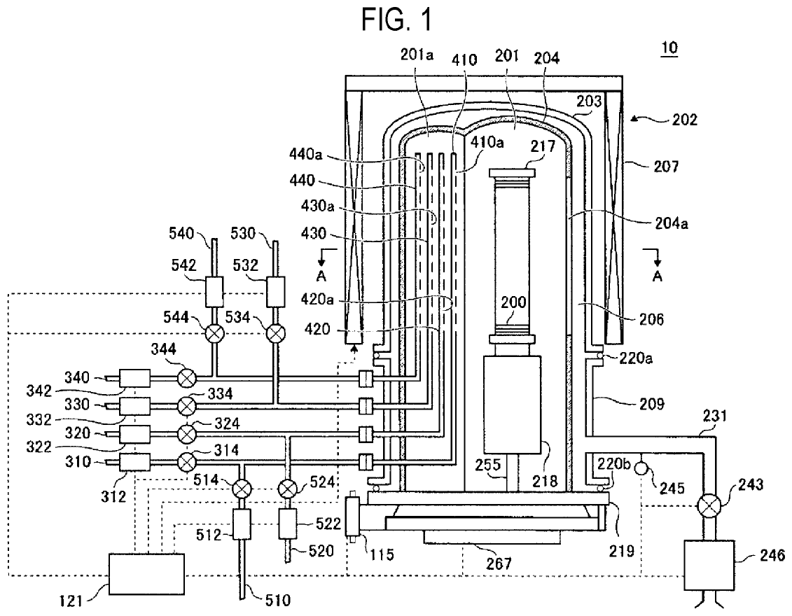

One embodiment of the present disclosure will now be described mainly with reference to FIGS. 1 to 5. The drawings used in the following description are schematic, and the dimensional relationship, ratios, and the like of various elements shown in the drawings do not always match the actual ones. Further, the dimensional relationship, ratios, and the like of various elements between plural figures do not always match each other.

### (1) Configuration of Substrate Processing Apparatus

A substrate processing apparatus 10 includes a process furnace 202 in which a heater 207 serving as a heating means (heating mechanism or heating system) is installed. The heater 207 is formed in a cylindrical shape and is vertically installed by being supported by a heater base (not shown) serving as a support plate.

Inside the heater 207, an outer tube 203 forming a process container is disposed concentrically with the heater 207. The outer tube 203 is made of, for example, a heat resistant material such as quartz or silicon carbide (SiC) and is formed in a cylindrical shape with a closed upper end and an open lower end. Below the outer tube 203, a manifold 209 (hereinafter referred to as MF 209) is disposed concentrically with the outer tube 203. The MF 209 is made of, for example, a metallic material such as stainless steel and is formed in a cylindrical shape with open upper and lower ends. An O-ring 220a serving as a seal is installed between an upper end portion of the MF 209 and the outer tube 203. The MF 209 being supported by the heater base allows the outer tube 203 to be vertically installed.

An inner tube 204 forming the process container is disposed at an inner side of the outer tube 203. The inner tube 204 is made of, for example, a heat resistant material such as quartz or SiC and is formed in a cylindrical shape with a closed upper end and an open lower end. The process container is mainly constituted by the outer tube 203, the inner tube 204, and the MF 209. A process chamber 201 is formed in a hollow cylindrical region (inside the inner tube 204) of the process container.

The process chamber 201 is configured to be capable of accommodating wafers 200 serving as substrates in a state in which the wafers 200 are arranged in a horizontal posture and in multiple stages in a vertical direction by a boat 217 which will be described later.

Nozzles 410, 420, 430, and 440 are installed in the process chamber 201 so as to penetrate through a sidewall of the MF 209 and the inner tube 204. Gas supply pipes 310, 320, 330, and 340 are connected to the nozzles 410, 420, 430, and 440, respectively. However, the process furnace 202 of this embodiment is not limited to the above-described configuration.

At the gas supply pipes 310, 320, 330, and 340, mass flow controllers (MFCs) 312, 322, 332, and 342, which are flow rate controllers (flow rate control parts), and valves 314, 324, 334, and 344, which are opening/closing valves, are respectively installed in this order from an upstream side. Gas supply pipes 510, 520, 530, and 540 for supplying an inert gas are respectively connected at downstream sides of the valves 314, 324, 334, and 344 of the gas supply pipes 310, 320, 330, and 340. At the gas supply pipes 510, 520, 530, and 540, MFCs 512, 522, 532, and 542, which are flow rate controllers (flow rate control parts), and valves 514, 524, 534, and 544, which are opening/closing valves, are respectively installed in this order from an upstream side.

The nozzles 410, 420, 430, and 440 are connected to tip end portions of the gas supply pipes 310, 320, 330, and 340, respectively. The nozzles 410, 420, 430, and 440 are configured as L-shaped nozzles, and horizontal portions of the nozzles 410,420, 430, and 440 are installed so as to penetrate through the sidewall of the MF 209 and the inner tube 204. Vertical portions of the nozzles 410, 420, 430, and 440 are installed inside a channel-shaped (groove-shaped) preliminary chamber 201a, which is formed so as to protrude outward in a radial direction of the inner tube 204 and extend in a vertical direction of the inner tube 204, and are also installed along an inner wall of the inner tube 204 in an upward direction of the preliminary chamber 201a (upward in an arrangement direction of the wafers 200).

The nozzles 410, 420, 430, and 440 are installed so as to extend from a lower region of the process chamber 201 to an upper region of the process chamber 201, and a plurality of gas supply holes 410a, 420a, 430a, and 440a are respectively installed at positions facing the wafers 200. Thus, a process gas is supplied from the gas supply holes 410a, 420a, 430a, and 440a of the respective nozzles 410, 420, 430, and 440 to the wafers 200. The plurality of gas supply holes 410a, 420a, 430a, and 440a are installed at height positions from a lower portion to an upper portion of the inner tube 204 with the same aperture area at the same aperture pitch. However, the gas supply holes 410a, 420a, 430a, and 440a are not limited to the above-described configuration. For example, the aperture area may be gradually increased from the lower portion to the upper portion of the inner tube 204. Consequently, flow rates of the gas supplied from the gas supply holes 410a, 420a, 430a, and 440a can be made more uniform.

The plurality of gas supply holes 410a, 420a, 430a, and 440a of the nozzles 410, 420, 430, and 440 are installed at height positions from a lower portion to an upper portion of the boat 217, which will be described later. Therefore, the process gas supplied into the process chamber 201 from the gas supply holes 410a, 420a, 430a, and 440a of the nozzles 410, 420, 430, and 440 is supplied to an entire region of the wafers 200, which are accommodated from the lower portion to the upper portion of the boat 217. The nozzles 410, 420, 430, and 440 are installed so as to extend from the lower region to the upper region of the process chamber 201, but may be installed so as to extend to a vicinity of a ceiling of the boat 217.

As a first precursor (first process gas), a first-element-containing gas containing a first element is supplied from the gas supply pipe 310 into the process chamber 201 via the MFC 312, the valve 314, and the nozzle 410.

As a second precursor (second process gas), a second-element-containing gas containing a second element is supplied from the gas supply pipe 320 into the process chamber 201 via the MFC 322, the valve 324, and the nozzle 420.

A first reactant (third process gas) is supplied from the gas supply pipe 330 into the process chamber 201 via the MFC 332, the valve 334, and the nozzle 430.

A second reactant (fourth process gas) is supplied from the gas supply pipe 340 into the process chamber 201 via the MFC 342, the valve 344, and the nozzle 440.

An inert gas such as a nitrogen (N₂) gas is supplied from the gas supply pipes 510, 520, 530, and 540 into the process chamber 201 via the MFCs 512, 522, 532, and 542, the valves 514, 524, 534, and 544, and the nozzles 410, 420, 430, and 440, respectively. Although an example using the N₂ gas as the inert gas is described here, a rare gas such as an Ar gas, a He gas, a Ne gas, a Xe gas, or the like may be used.

A process gas supply system mainly includes the gas supply pipes 310, 320, 330, and 340, the MFCs 312, 322, 332, and 342, the valves 314, 324, 334, and 344, and the nozzles 410, 420, 430, and 440, or the process gas supply system may include the nozzles 410, 420, 430, and 440. The process gas supply system may be simply referred to as a gas supply system. When the first precursor flows from the gas supply pipe 310, a first precursor supply system (also referred to as a first supply system or a first supplier) mainly includes the gas supply pipe 310, the MFC 312, and the valve 314. The first precursor supply system may also include the nozzle 410. Further, when the second precursor flows from the gas supply pipe 320, a second precursor supply system (also referred to as a second supply system) mainly includes the gas supply pipe 320, the MFC 322, and the valve 324. The second precursor supply system may also include the nozzle 420. Further, when the first reactant flows from the gas supply pipe 330, a first reactant supply system (also referred to as a third supply system or a second supplier) mainly includes the gas supply pipe 330, the MFC 332, and the valve 334. The first reactant supply system may also include the nozzle 430. Further, when the second reactant flows from the gas supply pipe 340, a second reactant supply system (also referred to as a fourth supply system or a third supplier) mainly includes the gas supply pipe 340, the MFC 342, and the valve 344. The second reactant supply system may also include the nozzle 440. Further, an inert gas supply system mainly includes the gas supply pipes 510, 520, 530, and 540, the MFCs 512, 522, 532, and 542, and the valves 514, 524, 534, and 544.

A method of supplying a gas in this embodiment is to supply a gas via the nozzles 410, 420, 430, and 440 disposed in the preliminary chamber 201a in which an annular vertically long space is defined by the inner wall of the inner tube 204 and end portions of a plurality of wafers 200. Then, the gas is ejected into the inner tube 204 from the plurality of gas supply holes 410a, 420a, 430a, and 440a installed at positions of the nozzles 410, 420, 430, and 440, which face the wafers 200.

An exhaust hole (exhaust port) 204a is an opening formed in a sidewall of the inner tube 204 at a position facing the nozzles 410, 420, 430, and 440. A shape of the opening is, for example, a slit shape. A gas supplied into the process chamber 201 from the gas supply holes 410a, 420a, 430a, and 440a of the nozzles 410, 420, 430, and 440 and flowing on surfaces of the wafers 200 passes through the exhaust hole 204a and flows into an exhaust path 206 constituted by a gap formed between the inner tube 204 and the outer tube 203. Then, the gas that flows into the exhaust path 206 flows into an exhaust pipe 231 and is discharged to an outside of the process furnace 202.

The exhaust hole 204a is installed at a position facing the plurality of wafers 200, and a gas supplied from the gas supply holes 410a, 420a, 430a, and 440a to a vicinity of the wafers 200 in the process chamber 201 flows toward the horizontal direction and then flows into the exhaust path 206 through the exhaust hole 204a. The exhaust hole 204a is not limited to the slit-shaped through-hole, but may be configured by a plurality of holes.

The exhaust pipe 231 for exhausting an internal atmosphere of the process chamber 201 is installed at the MF 209. A pressure sensor 245, which is a pressure detector (pressure detection part) for detecting an internal pressure of the process chamber 201, an auto pressure controller (APC) valve 243, and a pump 246 as an exhauster, are connected to the exhaust pipe 231 sequentially from an upstream side. The APC valve 243 can exhaust or stop exhausting the internal atmosphere of the process chamber 201 by opening or closing the valve while the pump 246 is actuated, and can also regulate the internal pressure of the process chamber 201 by adjusting an opening degree of the valve while the pump 246 is actuated. An exhaust system mainly includes the exhaust hole 204a, the exhaust path 206, the exhaust pipe 231, the APC valve 243, and the pressure sensor 245. The exhaust system may include the pump 246.

A seal cap 219 (hereinafter referred to as SC 219) serving as a furnace opening lid that is capable of hermetically sealing a lower end opening of the MF 209 is installed under the MF 209. The SC 219 is configured to come into contact with the lower end of the MF 209 from a lower side in the vertical direction. The SC 219 is made of, for example, metal such as stainless steel (SUS), and is formed in a disc shape. An O-ring 220b serving as a seal making contact with the lower end of the MF 209 is installed at an upper surface of the SC 219. A rotator 267 for rotating the boat 217 in which the wafers 200 are accommodated is installed at an opposite side of the process chamber 201 with respect to the SC 219. A rotary shaft 255 of the rotator 267 passes through the SC 219 and is connected to the boat 217. The rotator 267 is configured to rotate the wafers 200 by rotating the boat 217. The SC 219, which serves as an elevation mechanism vertically installed outside the outer tube 203, is configured to be raised or lowered in a vertical direction by a boat elevator 115 (hereinafter referred to as BE 115.) The BE 115 is configured to be able to load or unload the boat 217 into or out of the process chamber 201 by moving the SC 219 up and down. The BE 115 is configured as a transfer apparatus (transfer system) which transfers the boat 217 and the wafers 200 accommodated in the boat 217 into or out of the process chamber 201.

The boat 217 serving as a substrate support is configured so that a plurality of wafers 200, for example, 10 to 200 wafers 200, are arranged at intervals in the vertical direction in a horizontal posture. The boat 217 is made of, for example, a heat resistant material such as quartz or SiC. A heat insulating cylinder 218 configured as a cylinder made of a heat resistant material such as quartz or SiC is installed at the lower portion of the boat 217. With this configuration, heat from the heater 207 is less likely to be delivered to the SC 219 side. However, this embodiment is not limited to the above-described configuration. For example, instead of installing the heat insulating cylinder 218, heat insulating plates made of a heat resistant material such as quartz or SiC may be supported in a horizontal posture in multiple stages at the lower portion of the boat 217.

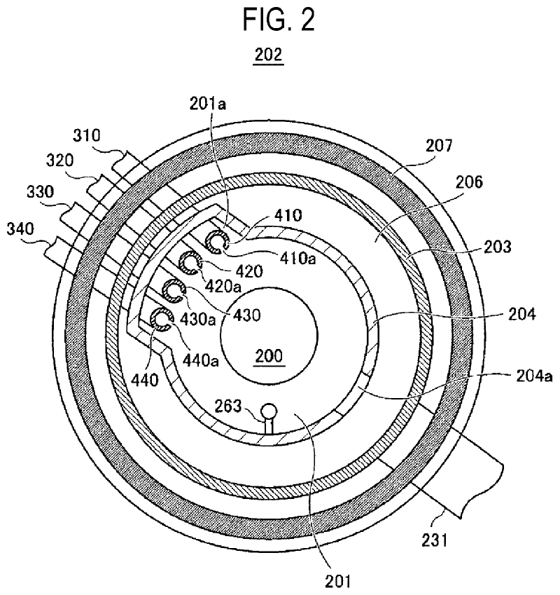

As shown in FIG. 2, a temperature sensor 263 serving as a temperature detector is installed in the inner tube 204. Based on temperature information detected by the temperature sensor 263, an amount of electric power supplied to the heater 207 is regulated such that an interior of the process chamber 201 falls within a desired temperature distribution. The temperature sensor 263 is configured as an L-shape, like the nozzles 410, 420, 430, and 440, and is installed along the inner wall of the inner tube 204.

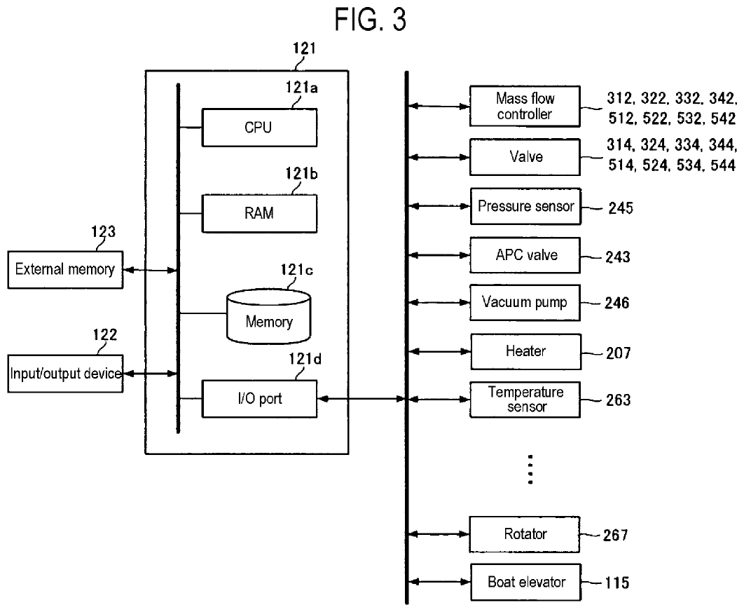

As shown in FIG. 3, a controller 121, which is a control part (control means or unit), is constituted as a computer including a central processing unit (CPU) 121a, a random access memory (RAM) 121b, a memory 121c, and an input/output (I/O) port 121d. The RAM 121b, the memory 121c, and the I/O port 121d are configured to be capable of exchanging data with the CPU 121a via an internal bus. An input/output device 122 constituted by, e.g., a touch panel or the like, is connected to the controller 121.

The memory 121c is constituted by, for example, a flash memory, a hard disk drive (HDD), or the like. The memory 121c stores, in a readable manner, a control program for controlling operations of the substrate processing apparatus and a process recipe in which sequences and conditions of a method of manufacturing a semiconductor device, which will be described later, are written. The process recipe functions as a program for causing the controller 121 to execute each process (each step) in the method of manufacturing a semiconductor device, which will be described later, to obtain a predetermined result. Hereinafter, the process recipe or the control program may be generally and simply referred to as a “program.” When the term “program” is used herein, it may indicate a case of including the process recipe, a case of including the control program, or a case of including a combination of the process recipe and the control program. The RAM 121b is constituted as a memory area (work area) in which a program or data read by the CPU 121a is temporarily stored.

The I/O port 121d is connected to the MFCs 312, 322, 332, 342, 512, 522, 532, and 542, the valves 314, 324, 334, 344, 514, 524, 534, and 544, the pressure sensor 245, the APC valve 243, the pump 246, the heater 207, the temperature sensor 263, the rotator 267, the BE 115, and the like.

The CPU 121a is configured to read and execute the control program from the memory 121c. The CPU 121a is also configured to read the recipe from the memory 121c according to an input of an operation command from the input/output device 122. The CPU 121a is configured to be capable of controlling flow rate regulation operations of various kinds of gases by the MFCs 312, 322, 332, 342, 512, 522, 532, and 542, opening/closing operations of the valves 314, 324, 334, 344, 514, 524, 534, and 544, opening/closing operations of the APC valve 243, pressure regulation operations performed by the APC valve 243 based on the pressure sensor 245, the temperature regulation operation performed by the heater 207 based on the temperature sensor 263, actuating and stopping of the pump 246, rotation operations of the boat 217 with the rotator 267 and adjusting a rotational speed of the boat 217, raising/lowering operations of the boat 217 by the BE 115, accommodation operation of the wafers 200 in the boat 217, and the like, according to contents of the read recipe.

The controller 121 may be configured by installing, on the computer, the aforementioned program stored in an external memory 123 (for example, a magnetic disk such as a hard disk, an optical disk such as a CD or a DVD, or a semiconductor memory such as a flash memory). The memory 121c or the external memory 123 are constituted as a non-transitory computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. The program (program product) may be provided to the computer using a communication means such as the Internet or a dedicated line, instead of using the external memory 123.

### (2) Substrate Processing Process (Substrate Processing Method)

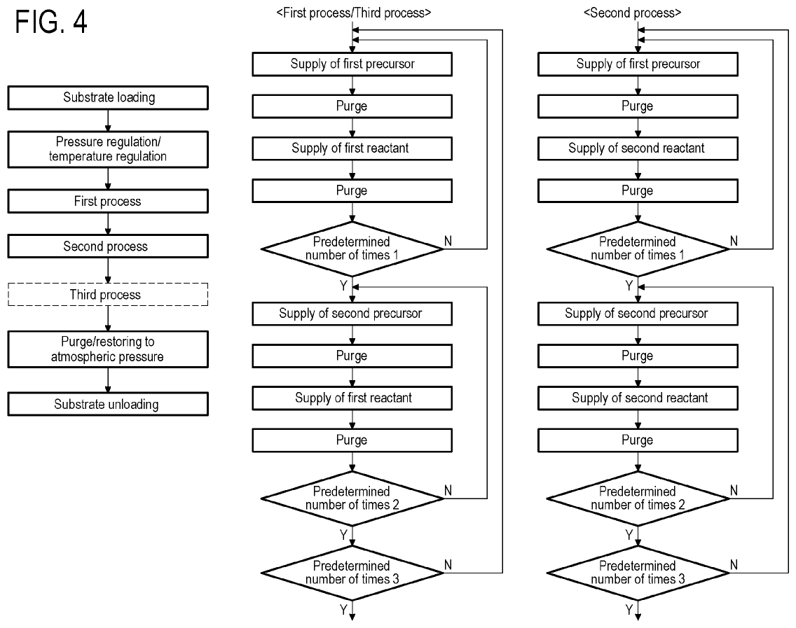

As one process of manufacturing a semiconductor device, an example of a process of forming a film on a wafer 200 will be described with reference to FIG. 4. This process is executed using the process furnace 202 of the above-described substrate processing apparatus 10. In the following description, operations of each component constituting the substrate processing apparatus 10 is controlled by the controller 121.

A substrate processing process (device manufacturing process) according to this embodiment includes:
(a) a process of supplying a first precursor to a wafer 200;
(b) a process of supplying a first reactant to the wafer 200 in a first amount;
(c) a process of supplying a second reactant to the wafer 200 in a second amount;
(d) a process of performing processes (a) and (b) a predetermined number of times to form a first layer on the wafer 200; and
(e) a process of performing processes (a) and (c) a predetermined number of times to form a second layer on the wafer 200.

When the term “wafer” is used in the present disclosure, it may refer to “a wafer itself” or “a stack including a wafer and a predetermined layer or film formed on a surface of the wafer.” When the phrase “a surface of a wafer” is used in the present disclosure, it may refer to “a surface of a wafer itself” or “a surface of the predetermined layer or film formed on the wafer.” When the term “substrate” is used in the present disclosure, it is synonymous with the term “wafer.”

### (WaferLoading)

When a plurality of wafers 200 are mounted into the boat 217, as shown in FIG. 1, the boat 217 supporting the plurality of wafers 200 is raised by the BE 115 to be loaded into the process chamber 201 of the process container and is accommodated in the process container.

### (Pressure Regulation and Temperature Regulation)

The interior of the process chamber 201, that is, a space in which the wafers 200 are placed, is exhausted by the pump 246 to reach a desired pressure. At this time, the internal pressure of the process chamber 201 is measured by the pressure sensor 245. The APC valve 243 is feedback-controlled based on the measured pressure information (pressure regulation). The pump 246 is kept in operation at least until processing on the wafers 200 is completed. The interior of the process chamber 201 is heated by the heater 207 to a desired temperature. At this time, the amount of electric power supplied to the heater 207 is feedback-controlled based on the temperature information detected by the temperature sensor 263 such that the interior of the process chamber 201 falls within a desired temperature distribution (temperature regulation). Heating the interior of the process chamber 201 by the heater 207 may be continuously performed at least until the processing on the wafers 200 is completed. In the process of forming a film on the wafer 200, control is performed so as to maintain the wafer 200 at a temperature of 150 to 400 degrees C. In the present specification, a numerical range expression such as “150 to 400 degrees C.” means that a lower limit value and an upper limit value are included in the range. Therefore, for example, “150 to 400 degrees C.” means “150 degrees C. or higher and 400 degrees C. or less.” The same applies to other numerical ranges.

### (Film-Forming Process)

Subsequently, a film-forming process is performed. In the film-forming process, as illustrated in FIG. 4, a first process, a second process, and a third process are performed. Note that the third process indicated by a broken line may be performed or may be omitted.

### (First Process)

The first process includes a process of forming a first-element-containing layer and a process of forming a second-element-containing layer.

### (Process of Forming First-Element-Containing Layer)

### (First Precursor Supply Process)

The valve 314 is opened to allow a first precursor to flow into the gas supply pipe 310. The first precursor whose flow rate is regulated by the MFC 312 is supplied into the process chamber 201 from the gas supply holes 410a of the nozzle 410, and is exhausted through the exhaust pipe 231.

At this time, a supply amount of the first precursor is regulated by regulating the APC valve 243 and the MFC 312. Processing conditions when supplying the first precursor are exemplified as follows:
First precursor supply flow rate (excluding dilution gas): 0.1 to 10 g/min, specifically 0.5 to 5 g/min
Inert gas (dilution gas) supply flow rate: 100 to 100,000 sccm, specifically 1,000 to 50,000 sccm
First precursor supply time: 10 to 600 seconds, specifically 30 to 300 seconds
Inert gas supply flow rate (per gas supply pipe): 0 to 50,000 sccm, specifically 5,000 to 15,000 sccm

At this time, the first precursor is supplied to the wafer 200. By supplying the first precursor to the wafer 200, a material containing the first element is adsorbed on the wafer 200 (an underlying film on the surface of the wafer 200).

As the first precursor, a gas containing molecules that contain the first element and ligands bonded to the first element may be used. Examples of the first element include metal elements, specifically transition metal elements, more specifically Group IV elements such as zirconium (Zr), hafnium (Hf), and titanium (Ti). Examples of ligands bonded to the first element include organic ligands, specifically hydrocarbon groups containing at least one selected from the group of alkyl groups such as methyl, ethyl, propyl, and butyl; amino groups (at least an NH-group); alkylamino groups; cyclopentadienyl groups; cyclohexadienyl groups; and cycloheptatrienyl groups. More specifically, the molecules contain the first element and an amine group and another group.

As the first precursor containing Zr as the first element, for example, a gas containing at least one selected from the group of tetrakis(ethylmethylamino) zirconium (Zr[N(CH₃)C₂H₅]₄), tetrakis(diethylamino) zirconium (Zr[N(C₂H₅)₂]₄), tetrakis(dimethylamino) zirconium (Zr[N(CH₃)₂]₄), Zr(MMP)₄, Zr(O-tBu)₄, and tris(dimethylamino)cyclopentadienyl zirconium ((C₅H₅)Zr[N(CH₃)₂]₃) may be used. One or more of these may be used as the first precursor.

As the first precursor containing Hf as the first element, for example, a gas containing at least one selected from the group of tetrakis(ethylmethylamino)hafnium (Hf[N(CH₃)C₂H₅]₄), tetrakis(diethylamino)hafnium (Hf[N(C₂H₅)₂]₄), tetrakis(dimethylamino)hafnium (Hf[N(CH₃)₂]₄), Hf(O-tBu)₄, Hf(MMP)₄, and tris(dimethylamino)cyclopentadienyl hafnium ((C₅H₅) Hf[N(CH₃)₂]₃) may be used. One or more of these may be used as the first precursor.

As the first precursor containing Ti as the first element, for example, a gas containing at least one selected from the group of tetrakis(ethylmethylamino)titanium (Ti[N(CH₃)C₂H₅]₄), tetrakis(diethylamino)titanium (Ti[N(C₂H₅)₂]₄), tetrakis(dimethylamino) titanium (Ti[N(CH₃)₂]₄), Ti(O-tBu)₄, Ti(MMP)₄, and tris(dimethylamino)cyclopentadienyl titanium ((C₅H₅) Ti[N(CH₃)₂]₃) may be used. One or more of these may be used as the first precursor.

### (Inert Gas Supply (Purge) Process)

After a predetermined time elapses since the start of supplying the first precursor, the valve 314 is closed to stop the supply of the first precursor. At this time, the valves 514, 524, 534, and 544 are opened to allow an inert gas to flow into the gas supply pipes 510, 520, 530, and 540 (purge). That is, the inert gas is supplied into the process chamber 201.

At this time, the APC valve 243 is regulated to set the internal pressure of the process chamber 201 to, for example, a pressure within a range of 1 to 3,990 Pa. Flow rates of the inert gas controlled by the MFCs 512, 522, 532, and 542 are each set to, for example, a flow rate within a range of 0.1 to 30 slm.

### (Exhaust (Purge) Process)

After a predetermined time elapses since the start of supplying the inert gas, the valves 514, 524, 534, and 544 are closed to stop the supply of the inert gas. At this time, the APC valve 243 of the exhaust pipe 231 is opened, and the process chamber 201 is vacuum-exhausted by the pump 246. Accordingly, residual gas is removed from the wafer 200, and gas and reaction by-products remaining in the process chamber 201 are removed from the process chamber 201. As a result, an amount of the first precursor remaining in the process chamber 201 and an amount of decomposition products can be reduced by removing the residual gas from the wafer 200. At this time, a vacuum-exhaustion time of the process chamber 201 is set to, for example, within a range of 0.1 to 30 seconds.

In the purge process, at least one selected from the group of the inert gas supply process and the exhaust process is performed.

### (First Reactant Supply Process)

Subsequently, the valve 334 is opened to allow a first reactant to flow into the gas supply pipe 330. The first reactant is flow-rate-controlled by the MFC 332, supplied into the process chamber 201 from the gas supply holes 430a of the nozzle 430, and exhausted through the exhaust pipe 231.

At this time, the APC valve 243 and the MFC 332 are regulated to set a supply amount of the first reactant to a first amount. Processing conditions when supplying the first reactant are exemplified as follows:
First reactant supply flow rate: 100 to 100,000 sccm, specifically 1,000 to 10,000 sccm. Alternatively, the flow rate may be 0.1 to 10 g/min, specifically 0.2 to 5 g/min.
Supply time: 10 to 600 seconds, specifically 30 to 300 seconds
Inert gas supply flow rate (per gas supply pipe): 0 to 50,000 sccm, specifically 5,000 to 15,000 sccm

At this time, the first reactant is supplied to the wafer 200. Here, as the first reactant, for example, an oxidizing agent (oxidizing gas) may be used. Examples of the oxidizing agent include a gas containing oxygen (O), and an O- and hydrogen (H)-containing gas. Examples of the O- and H-containing gas include water vapor (H₂O gas), hydrogen peroxide (H₂O₂) gas, hydrogen (H₂) gas+oxygen (O₂) gas, H₂ gas+ozone (O₃) gas, and the like. Examples of the gas containing O include O₂ gas and O₃ gas. One or more of these may be used as the oxidizing agent. In the present disclosure, a description in which two gases are listed together, such as “H₂ gas+O₂ gas,” means a mixed gas of H₂ gas and O₂ gas. When supplying the mixed gas, the two gases may be mixed in a supply pipe (pre-mixed) before being supplied into the process chamber 201, or may be supplied separately into the process chamber 201 through different supply pipes and mixed in the process chamber 201 (post-mixed). O₃ can be generated from, for example, O₂ gas by an ozonizer. Therefore, a nozzle from the ozonizer discharges a gas including 02 and O₃. The O₃ generated as such is supplied to the process container and the wafer 200. Specifically, an oxidizing agent supply nozzle provides O₂ gas+O₃ gas. Further, other nozzles may provide an inert gas, and supplying the inert gas can prevent O₃ gas from entering those nozzles. In a case where the oxidizing agent supply nozzle does not supply both the oxidizing agent and the inert gas, the oxidizing agent supply nozzle and the other nozzles supply O₃, O₂, and the inert gas to the process container and the wafer 200. The term “agent” used in the present disclosure includes at least one selected from the group of a gaseous substance and a liquid substance. The liquid substance includes a mist-like substance. That is, a film-forming agent, a modifying agent, and an etching agent may include a gaseous substance, may include a liquid substance such as a mist-like substance, or may include both.

### (Inert Gas Supply Process)

After a predetermined time elapses since the start of supplying the first reactant, the valve 334 is closed to stop the supply of the first reactant. At this time, the valves 514, 524, 534, and 544 are opened to allow an inert gas to flow into the gas supply pipes 510, 520, 530, and 540. That is, the inert gas is supplied into the process chamber 201.

At this time, the APC valve 243 is regulated to set the internal pressure of the process chamber 201 to, for example, a pressure within the range of 1 to 3,990 Pa. The flow rates of the inert gas controlled by the MFCs 512, 522, 532, and 542 are each set to, for example, within the range of 0.1 to 30 slm. At this time, a supply time of the inert gas to the wafer 200 is set to, for example, within the range of 0.1 to 30 seconds.

At this time, the inert gas is supplied into the process chamber 201. As a result, unreacted first reactant remaining in the process chamber 201 or the first reactant remaining after contributing to film formation, as well as reaction byproducts, can be reduced.

### (Exhaust Process)

After a predetermined time elapses since the start of supplying the inert gas, the valves 514, 524, 534, and 544 are closed to stop the supply of the inert gas. At this time, the APC valve 243 of the exhaust pipe 231 is opened, and the process chamber 201 is exhausted by the pump 246. Accordingly, residual gas is removed from the wafer 200, and unreacted first reactant remaining in the process chamber 201 or first reactant after contributing to film formation, as well as reaction by-products, are removed from the process chamber 201. At this time, the vacuum-exhaustion time of the process chamber 201 is set to, for example, within the range of 0.1 to 30 seconds.

### (Predetermined Number of Times 1)

By performing, in order, the above-described first precursor supply process to exhaust process a predetermined number of times (A times, where A is an integer of 1 or more), a first first-element-containing layer with a predetermined thickness is formed on the wafer 200.

### (Process of Forming Second-Element-Containing Layer)

### (Second Precursor Supply Process)

The valve 324 is opened to allow a second precursor to flow into the gas supply pipe 320. The second precursor whose flow rate is adjusted by the MFC 322 is supplied into the process chamber 201 from the gas supply holes 420a of the nozzle 420, and is exhausted through the exhaust pipe 231.

At this time, a supply amount of the second precursor is regulated by regulating the APC valve 243 and the MFC 322. Processing conditions when supplying the second precursor are exemplified as follows:
Second precursor supply flow rate (excluding dilution gas): 0.1 to 10 g/min, specifically 0.5 to 5 g/min
Inert gas (dilution gas) supply flow rate: 100 to 100,000 sccm, specifically 1,000 to 50,000 sccm
Second precursor supply time: 10 to 600 seconds, specifically 30 to 300 seconds
Inert gas supply flow rate (per gas supply pipe): 0 to 50,000 sccm, specifically 5,000 to 15,000 sccm

At this time, the second precursor is supplied to the wafer 200. By supplying the second precursor to the wafer 200, a material containing a second element is adsorbed on the wafer 200 (an underlying film on the surface of the wafer 200).

As the second precursor, a gas containing molecules that contain a second element and ligands bonded to the second element may be used. The second element may be the same as the first element or may be a different element, and is specifically a different element. As specific materials for the second precursor, the materials described above as the first precursor may be used.

### (Inert Gas Supply Process)

After a predetermined time elapses since the start of supplying the second precursor, the valve 324 is closed to stop the supply of the second precursor. At this time, the valves 514, 524, 534, and 544 are opened to allow an inert gas to flow into the gas supply pipes 510, 520, 530, and 540 (purge). That is, the inert gas is supplied into the process chamber 201.

At this time, the APC valve 243 is regulated to set the internal pressure of the process chamber 201 to, for example, a pressure within the range of 1 to 3,990 Pa. The flow rates of the inert gas controlled by the MFCs 512, 522, 532, and 542 are each set to, for example, within the range of 0.1 to 30 slm.

### (Exhaust Process)

After a predetermined time elapses since the start of supplying the inert gas, the valves 514, 524, 534, and 544 are closed to stop the supply of the inert gas. At this time, the APC valve 243 of the exhaust pipe 231 is opened, and the process chamber 201 is vacuum-exhausted by the pump 246. Accordingly, residual gas is removed from the wafer 200, and gases remaining in the process chamber 201 and reaction by-products are removed from the process chamber 201. As a result, an amount of the second precursor remaining in the process chamber 201 and the amount of decomposition products can be reduced by removing residual gas from the wafer 200. At this time, the vacuum-exhaustion time of the process chamber 201 is set to, for example, within the range of 0.1 to 30 seconds.

### (First Reactant Supply Process)

Subsequently, a first reactant supply process is performed in the same manner as described above. Supply conditions of the first reactant in the process of forming the second-element-containing layer can also be set similarly to the supply conditions of the first reactant in the process of forming the first-element-containing layer.

### (Inert Gas Supply Process)

After a predetermined time elapses since the start of supplying the first reactant, an inert gas supply process is performed in the same manner as described above.

### (Exhaust Process)

After a predetermined time elapses since the start of supplying the inert gas, an exhaust process is performed in the same manner as described above.

### (Predetermined Number of Times 2)

By performing, in order, the above-described second precursor supply process to exhaust process a predetermined number of times (B times, where B is an integer of 1 or more), a first second-element-containing layer with a predetermined thickness is formed on the wafer 200.

### (Predetermined Number of Times 3)

By performing, in order, the process of forming the first-element-containing layer (forming the first first-element-containing layer) and the process of forming the second-element-containing layer (forming the first second-element-containing layer) a predetermined number of times (C times, where C is an integer of 1 or more), the first first-element-containing layer and the first second-element-containing layer are stacked on the wafer 200. This stacked structure is referred to as a first layer. The first layer is a layer that is capable of being crystallized by a modification process to be described later.

### (Second Process)

Subsequently, a second process is performed. As illustrated in FIG. 4, the second process is performed in the same manner as the first process, except that the first reactant supply process is replaced with a second reactant supply process. In the following, a reactant supply process (second reactant supply process) that differs from that of the first process will be described in detail, and detailed descriptions of the same processes will be omitted.

### (Process of Forming First-Element-Containing Layer)

The process of forming a first-element-containing layer in the second process is performed in a flow in which the first reactant supply process in the process of forming the first-element-containing layer in the first process is replaced with a second reactant supply process.

### (Purge Process)

In the same procedure as described above, at least one selected from the group of an inert gas supply process and an exhaust process is performed.

### (Second Reactant Supply Process)

The valve 344 is opened to allow a second reactant to flow into the gas supply pipe 340. The second reactant is flow-rate-controlled by the MFC 342, supplied into the process chamber 201 from the gas supply holes 440a of the nozzle 440, and exhausted through the exhaust pipe 231.

At this time, the APC valve 243 and the MFC 342 are regulated to set a supply amount of the second reactant to a second amount. Processing conditions when supplying the second reactant are exemplified as follows:
Second reactant supply flow rate: 100 to 100,000 sccm, specifically 1,000 to 10,000 sccm.
Alternatively, the flow rate may be 0.01 to 10 g/min, specifically 0.1 to 2 g/min.
Supply time: 10 to 600 seconds, specifically 30 to 300 seconds
Inert gas supply flow rate (per gas supply pipe): 0 to 50,000 sccm, specifically 5,000 to 15,000 sccm

An oxidizing power of the second reactant may be set to be different from an oxidizing power of the first reactant. That is, supply conditions (supply amount and gas species) of the second reactant may be set such that the oxidizing power of the second reactant becomes smaller (weaker) than the oxidizing power of the first reactant.

For example, when a material (gas species) of the first reactant and a material of the second reactant are the same, the second amount, which is the supply amount of the second reactant, is set to be different from the first amount, which is the supply amount of the first reactant. Specifically, for example, the second amount as the supply amount of the second reactant is set to be smaller than the first amount as the supply amount of the first reactant. Here, the supply amount is regulated by controlling at least one selected from the group of a supply flow rate and a supply time. Specifically, the supply flow rate of the second reactant is set to be smaller than the supply flow rate of the first reactant. In addition, the supply time of the second reactant is set to be shorter than the supply time of the first reactant. A partial pressure of the second reactant may also be set to be smaller than a partial pressure of the first reactant.

The oxidizing power may be regulated by making the material of the first reactant different from the material of the second reactant. For example, among oxidizing agents of the present disclosure, a gas containing O₃, an H₂O₂ gas, and a gas obtained by activating a gas of the present disclosure are of relatively stronger oxidizing power than other gases of the present disclosure. For example, by using at least one selected from the group of O₃, H₂O₂, and an activated gas of H₂+O₂ as the first reactant, and using at least one selected from the group of O₂, H₂O, and H₂+O₂ as the second reactant, the oxidizing power of the second reactant can be made weaker than the oxidizing power of the first reactant.

The oxidizing power may be regulated by combining regulation based on a combination of materials and regulation of supply conditions.

### (Purge Process)

In the same procedure as described above, at least one selected from the group of an inert gas supply process and an exhaust process is performed.

### (Predetermined Number of Times 1)

By performing, in order, processes including the above-described second reactant supply process a predetermined number of times (D times, where D is an integer of 1 or more), a second first-element-containing layer with a predetermined thickness is formed on the wafer 200.

### (Process of Forming Second-Element-Containing Layer)

The process of forming the second-element-containing layer in the second process is performed in a flow in which the first reactant supply process in the process of forming the second-element-containing layer in the first process is replaced with the above-described second reactant supply process.

### (Predetermined Number of Times 2)

By performing, in order, processes including the above-described second reactant supply process a predetermined number of times (E times, where E is an integer of 1 or more), a second second-element-containing layer with a predetermined thickness is formed on the wafer 200.

### (Predetermined Number of Times 3)

By performing, in order, the process of forming the first-element-containing layer (forming the second first-element-containing layer) and the process of forming the second-element-containing layer (forming the second second-element-containing layer) a predetermined number of times (F times, where F is an integer of 1 or more), the second first-element-containing layer and the second second-element-containing layer are stacked on the wafer 200. This stacked structure is referred to as a second layer. Here, since the second layer is formed using the second reactant, the second layer is configured such that an amount of oxygen contained in the second layer is smaller than an amount of oxygen contained in the first layer. The second layer is a layer that is capable of containing an amorphous phase by the modification process to be described later.

### (Third Process)

Subsequently, a third process may be performed. The flow and various conditions of the third process are set to be different from those of the second process. Further, the flow and various conditions of the third process may be the same as those of the first process, or may be appropriately different from those of the first process.

A process of forming a film in which the first layer and the second layer are stacked on the wafer 200 is performed in this manner.

In a specific embodiment of the present disclosure, for example, a gas containing Hf may be used as the first precursor. For example, a gas containing Zr may be used as the second precursor. By forming an oxide film containing Hf and Zr in this manner, it is possible to form a film of a ferroelectric material with an extremely high dielectric constant.

In each of the first layer and the second layer, an oxide film containing Hf and Zr is formed. However, as described above, due to the relationship between the oxidizing power of the first reactant and the oxidizing power of the second reactant, in the formed layer, the amount of oxygen contained in the second layer is smaller than the amount of oxygen contained in the first layer. A ratio between the first element and the second element contained in the first layer is close to a ratio between the first element and the second element contained in the second layer. In other words, the ratio between the first element and the second element is substantially the same in each of the first layer and the second layer. From this relationship, the second layer may also be referred to as an oxygen-poor layer relative to the first layer. The second layer may also be referred to as a layer that is more deficient in oxygen than the first layer. Conversely, the first layer may be referred to as an oxygen-rich layer relative to the second layer. Further, while the first layer includes a composition close to a stoichiometric composition, the second layer may be referred to as an oxygen-poor layer relative to the stoichiometric composition.

The above-described first process (and third process) can be represented by sequence (A) below. In addition, the second process can be represented by sequence (B) below. The first process (and third process) may alternatively be carried out in modified forms as shown in (C) or (D) below. Further, the second process may alternatively be carried out in modified forms as shown in (E) or (F) below. The following is described with purge processes omitted. The sequence can be configured so that the purge process is omitted.

[(first precursor supply→first reactant supply)×A→(second precursor supply→first reactant supply)×B]×C (A)

[(first precursor supply→second reactant supply)×D→(second precursor supply→second reactant supply)×E]×F (B)

(first precursor supply→first reactant supply→second precursor supply)×C (C)

(first precursor supply→second precursor supply→first reactant supply)×C (D)

(first precursor supply→second reactant supply→second precursor supply)×F (E)

(first precursor supply→second precursor supply→second reactant supply)×F (F)

### (Purge and Restoring to Atmospheric Pressure)

An inert gas is supplied into the process chamber 201 from each of the gas supply pipes 510 to 540 and is exhausted through the exhaust pipe 231. The inert gas acts as a purge gas, whereby the process chamber 201 is purged with the inert gas, and gases and reaction by-products remaining in the process chamber 201 are removed from the process chamber 201. Thereafter, the atmosphere in the process chamber 201 is replaced with the inert gas, and the pressure in the process chamber 201 is returned to the atmospheric pressure.

### (Wafer Unloading)

Thereafter, the SC 219 is lowered by the BE 115 to open a lower end of the outer tube 203. Then, the processed wafers 200 supported by the boat 217 are unloaded to an outside of the outer tube 203 from the lower end of the outer tube 203. Thereafter, the processed wafers 200 are removed from the boat 217.

### (Modification Process)

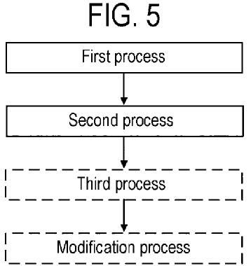

As illustrated in FIG. 5, a modification process may be performed on the wafer 200 on which the first layer and the second layer are formed. The modification process may be executed in the same substrate processing apparatus 10 continuously after the above-described first process, second process (and third process). Alternatively, after the above-described wafer unloading, the wafer 200 may be transferred to a substrate processing apparatus 10 different from the substrate processing apparatus 10 that performed the first process, second process (and third process), and the modification process may be performed.

In the modification process, for example, heat treatment for heating the wafer 200 or plasma treatment can be performed. When the film formed on the wafer 200 is a dielectric (particularly a ferroelectric), heat treatment (annealing) may be performed. The heat treatment is performed by heating the wafer 200 to a temperature higher than that in the film-forming process. For example, the wafer 200 is heated to 350 degrees C. to 800 degrees C. to perform the heat treatment. By the modification process, the first layer is crystallized, and the second layer is modified into a layer that contains an amorphous phase.

### (3) Effects of the Present Embodiment

According to the present embodiment, one or more of the following effects can be obtained.
(a) By making the amount of oxygen contained in the second layer smaller than the amount of oxygen contained in the first layer, when the modification process (e.g., heat treatment) is performed, the first layer can be crystallized and the second layer can be made a layer containing an amorphous phase.
(b) When a dielectric layer is crystallized, the dielectric constant of the dielectric can be improved. In particular, in a ferroelectric, ferroelectric properties can be exhibited. On the other hand, there may be a problem of increasing leak current due to grain boundaries of the crystal. In the present disclosure, a structure in which a crystallized first layer and a second layer containing an amorphous phase are stacked is formed. Grain boundaries in such a second layer are fewer than grain boundaries in the first layer. As a result, even when a path through which a leak current can occur exists in the first layer, the second layer can block (interrupt) the path through which the leak current can occur. Therefore, the leak current can be suppressed.

### (4) Other Embodiments

The embodiments of the present disclosure are specifically described above. However, the present disclosure is not limited to the above-described embodiments, and various modifications can be made without departing from the spirit of the present disclosure.

In the above embodiments, a case where an oxidizing agent is used as the first reactant and the second reactant is described. However, the present disclosure is not limited thereto. For example, when forming a film of a metal alone, rather than an oxide film, as a film to be formed on the wafer 200, a reducing agent may be used. Examples of the reducing agent include hydrogen-containing gases such as H₂ gas and deuterium (D₂) gas. Further, when forming a nitride film, a nitriding agent may be used. As the nitriding agent, a gas containing nitrogen may be used. Specifically, at least one selected from the group of NH₃ gas, N₂H₄ gas, and N₂H₂ gas may be used. Note that each of the nitriding agent, the reducing agent, and the oxidizing agent may be a gas obtained by activating at least one of the gases of the present disclosure.

Process recipes (programs in which processing procedures, processing conditions, and the like are described) used for forming these various thin films may be prepared individually (in plural) in accordance with contents of substrate processing (film type, composition ratio, film quality, film thickness, processing procedures, processing conditions, etc.). When starting substrate processing, an appropriate process recipe may be selected from among a plurality of process recipes according to the contents of substrate processing. Specifically, the plurality of process recipes (program products) individually prepared according to the contents of substrate processing may be stored (installed) in advance in the memory 121c of the substrate processing apparatus via a telecommunication line or a recording medium (external memory 123) in which the process recipes are recorded. When starting substrate processing, the CPU 121a of the substrate processing apparatus may appropriately select an appropriate process recipe, according to the contents of substrate processing, from among the plurality of process recipes stored in the memory 121c. With this configuration, various thin films of different film types, composition ratios, film qualities, and film thicknesses can be formed in a versatile manner and with good reproducibility by one substrate processing apparatus. Further, an operator's operation burden (e.g., an input burden of processing procedures and processing conditions) can be reduced, and substrate processing can be started promptly while avoiding operation errors.

The present disclosure can also be realized, for example, by changing a process recipe of an existing substrate processing apparatus. When changing the process recipe, it is possible to install the process recipe according to the present disclosure in the existing substrate processing apparatus via a telecommunication line or a recording medium in which the process recipe is recorded. It is also possible to operate an input/output device of the existing substrate processing apparatus to change the process recipe itself to the process recipe according to the present disclosure.

The present disclosure can be applied to, for example, a word line portion of a NAND flash memory with a three-dimensional structure, a DRAM, or the like.

In the above-described embodiments and modifications, an example in which a film is formed using a batch-type substrate processing apparatus that processes a plurality of wafers 200 at a time is described. The present disclosure is not limited thereto, and can be suitably applied also to a case of forming a film using a single-wafer-type substrate processing apparatus that processes one wafer 200 or several wafers 200 at a time. Further, in the above-described embodiments, an example in which a film is formed using a substrate processing apparatus including a hot-wall-type process furnace is described. The present disclosure is not limited thereto, and can be suitably applied also to a case of forming a film using a substrate processing apparatus including a cold-wall-type process furnace.

In the above-described embodiments, an example in which the above-described processing sequence is performed in the same process chamber of the same processing apparatus (in situ) is described. The present disclosure is not limited thereto. For example, one step of the above-described processing sequence and another step may be performed in different process chambers of different processing apparatuses (ex situ), or may be performed in different process chambers of the same processing apparatus.

Even when using these substrate processing apparatuses, each process can be performed with processing procedures and processing conditions similar to those in the above-described embodiments and modifications, and effects similar to those in the above-described embodiments and modifications can be obtained.

The above-described embodiments and modifications can be used in combination as appropriate. In such a case, processing procedures and processing conditions can be, for example, the same as the processing procedures and processing conditions of the above-described embodiments and modifications.

According to the present disclosure in some embodiments, it is possible to improve the characteristics of a film.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a first precursor to the substrate;
(b) supplying a first reactant to the substrate in a first amount;
(c) supplying a second reactant to the substrate in a second amount;
(d) performing (a) and (b) a predetermined number of times to form a first layer on the substrate; and
(e) performing (a) and (c) a predetermined number of times to form a second layer on the substrate.

2. The method of claim 1, wherein the first amount is different from the second amount.

3. The method of claim 1, wherein the second amount is smaller than the first amount.

4. The method of claim 1, further comprising:
performing (d) and (e) a predetermined number of times to stack the first layer and the second layer.

5. The method of claim 1, further comprising:
(f) supplying a second precursor to the substrate,
wherein (d) includes performing (a), (b), and (f) a predetermined number of times, and
wherein (e) includes performing (a), (c), and (f) a predetermined number of times.

6. The method of claim 5, wherein the first precursor contains a first element, and the second precursor contains a second element, and
wherein a ratio between the first element and the second element contained in the first layer is substantially the same as a ratio between the first element and the second element contained in the second layer.

7. The method of claim 1, further comprising:
(g) modifying the first layer and the second layer.

8. The method of claim 7, wherein (g) includes crystallizing the first layer and modifying the second layer into a layer containing an amorphous phase.

9. The method of claim 7, wherein the first layer is a layer capable of being crystallized by the modification, and the second layer is a layer capable of containing an amorphous phase by the modification.

10. The method of claim 7, wherein the modification is a heat treatment.

11. The method of claim 1, wherein an oxidizing power of the first reactant is different from an oxidizing power of the second reactant.

12. The method of claim 1, wherein an oxidizing power of the second reactant is weaker than an oxidizing power of the first reactant.

13. The method of claim 1, wherein a supply amount of the first reactant is different from a supply amount of the second reactant.

14. The method of claim 1, wherein a supply amount of the second reactant is smaller than a supply amount of the first reactant.

15. The method of claim 1, wherein a partial pressure of the second reactant is smaller than a partial pressure of the first reactant.

16. The method of claim 1, wherein a supply flow rate of the second reactant is smaller than a supply flow rate of the first reactant.

17. The method of claim 1, wherein materials of the first reactant and the second reactant are different.

18. A method of manufacturing a semiconductor device, comprising the method of claim 1.

19. A non-transitory computer-readable recording medium storing a program that causes, by a computer, a substrate processing apparatus to perform a process comprising:
(a) supplying a first precursor to a substrate;
(b) supplying a first reactant to the substrate in a first amount;
(c) supplying a second reactant to the substrate in a second amount;
(d) performing (a) and (b) a predetermined number of times to form a first layer on the substrate; and
(e) performing (a) and (c) a predetermined number of times to form a second layer on the substrate.

20. A substrate processing apparatus comprising:
a first supplier configured to supply a first precursor to a substrate;
a second supplier configured to supply a first reactant to the substrate;
a third supplier configured to supply a second reactant to the substrate; and
a controller configured to be capable of controlling the first supplier, the second supplier, and the third supplier so as to perform a process including:
(a) supplying the first precursor to the substrate;
(b) supplying the first reactant to the substrate in a first amount;
(c) supplying the second reactant to the substrate in a second amount;
(d) performing (a) and (b) a predetermined number of times to form a first layer on the substrate; and
(e) performing (a) and (c) a predetermined number of times to form a second layer on the substrate.
